(19) United States
(12) Patent Application Publication
(10) Pub. No.: US 2026/0223730 A1
(43) Pub. Date: Jul. 30, 2026

(54) METHOD FOR MANUFACTURING COMPONENT, COMPONENT, AND HYBRID BONDING EQUIPMENT

(71) Applicant: Panasonic Intellectual Property Management Co., Ltd., Osaka (JP)

(72) Inventor: ATSUNORI MOCHIDA, Osaka (JP)

(21) Appl. No.: 19/452,937

(22) Filed: Jan. 20, 2026

(30) Foreign Application Priority Data
Jan. 29, 2025 (JP) 2025-012890

(51) Int. Cl. H10W 80/00; H10W 72/00; H10W 72/90; H10W 90/00; H10W 90/20

(52) U.S. Cl. CPC H10W 80/312; H10W 72/011; H10W 72/01953; H10W 72/01955; H10W 72/01961; H10W 72/923; H10W 72/934; H10W 72/952; H10W 80/163; H10W 80/327; H10W 80/331; H10W 90/20; H10W 90/792

(57) ABSTRACT

A method for manufacturing a component obtained by bonding a first member and a second member includes forming a first metal layer on a first substrate, forming a resist pattern on the first metal layer, forming a first metal pattern using a resist pattern, forming a first insulating film on the first substrate with the resist pattern left, removing the first insulating film covering the resist pattern to obtain the first member with the first metal pattern and the first insulating film covering a side surface of the first metal pattern, preparing a second member includes a second metal pattern and a second insulating film covering a side surface of the second metal pattern on a second substrate, performing predetermined treatment on the first member and the second member, bonding the first insulating film and the second insulating film, and bonding the first metal pattern and the second metal pattern.

### BACKGROUND

### Technical Field

The present disclosure relates to a component formed by bonding two members each having a front surface provided with a metal pattern and an insulating film surrounding the metal pattern, a method for manufacturing the component, and a hybrid bonding equipment.

### Description of the Related Art

In recent years, densification of semiconductor elements and narrowing pitch of wiring parts have been advanced for energy saving of semiconductor devices. In particular, development of three-dimensional stacking technique enables chips different in function to be vertically stacked, thereby improving a degree of integration of devices. As the three-dimensional stacking technique, a hybrid bonding technique is used, for example.

The hybrid bonding technique is a method for bonding semiconductor wafers to each other (wafer to wafer), a semiconductor chip and a semiconductor wafer (die to wafer), or a semiconductor chip and a semiconductor chip (die to die) without using bumps, solder balls, or the like when a semiconductor element is mounted on a substrate. Besides bonding of semiconductors identical in type, the hybrid bonding technique has been reported to be applied to bonding of a semiconductor chip and a wiring substrate, and bonding between dissimilar semiconductors. The hybrid bonding technique also has been studied to be applied to bonding between a mounting substrate such as a glass substrate and an interposer, or bonding between rewiring layers constituting the interposer.

For example, Patent Literature (PTL) 1 discloses a hybrid bonding technique of a semiconductor chip and a semiconductor wafer that have front surfaces covered with insulating films at least one of which is made of an organic material. Even when foreign matter is interposed between contact surfaces of the semiconductor chip and the semiconductor wafer, the configuration described above enables the insulating film made of the organic material to be deformed to contain the foreign matter. Consequently, bonding failure can be reduced while fine bonding of the semiconductor chip is performed.

PTL 1: Japanese Patent No. 7543712

### SUMMARY

To achieve an object as described above, a method for manufacturing a component according to the present disclosure, the component being obtained by bonding a first member and a second member, the method including at least a metal layer formation step, a resist pattern formation step, a metal pattern formation step, an insulating film formation step, a resist lift-off step, a second member preparation step, a surface treatment step, a bonding step, and an annealing step. The metal layer formation step is performed to form a first metal layer on a front surface of a first substrate. The resist pattern formation step is performed to form a resist pattern on a front surface of the first metal layer. The metal pattern formation step is performed to form a first metal pattern by removing the first metal layer using the resist pattern as a mask. The insulating film formation step is performed to form a first insulating film on the front surface of the first substrate with the resist pattern left on a front surface of the first metal pattern. The resist lift-off step is performed to remove the first insulating film covering the resist pattern together with the resist pattern to obtain the first member with a front surface provided with the first metal pattern and the first insulating film provided covering a side surface of the first metal pattern. The second member preparation step is performed to prepare the second member in which a second metal pattern and a second insulating film provided covering a side surface of the second metal pattern are formed on a front surface of a second substrate. The surface treatment step is performed to perform predetermined treatment on the front surface of the first member after the resist lift-off step is performed and on a front surface of the second member. The bonding step is performed, after the surface treatment step is performed, to align the first member and the second member such that the front surface of the first member and the front surface of the second member face each other, and to bond the first insulating film and the second insulating film. The annealing step is performed to bond the first metal pattern and the second metal pattern by heating the first member and the second member to a predetermined temperature after the surface treatment step is performed.

A component according to the present disclosure is obtained by bonding a first member and a second member. The first member includes a first metal pattern disposed on a front surface of a first substrate and a first insulating film covering a side surface of the first metal pattern. The second member includes a second metal pattern disposed on a front surface of a second substrate and a second insulating film covering a side surface of the second metal pattern. The first insulating film and the second insulating film are bonded, and the first metal pattern and the second metal pattern are bonded. At least the first metal pattern includes a first layer exposed on a front surface of the first metal pattern, and a second layer disposed between the first layer and the first substrate. The second layer is not disposed between the side surface of the first metal pattern and a side surface of the first insulating film.

A hybrid bonding equipment according to the present disclosure is configured to bond a first member and a second member, and includes at least a plasma treatment chamber, a hydrophilization treatment chamber, a bonding treatment chamber, and a conveyance path. The first member includes a first metal pattern disposed on a front surface of a first substrate and a first insulating film covering a side surface of the first metal pattern. The second member includes a second metal pattern disposed on a front surface of a second substrate and a second insulating film covering a side surface of the second metal pattern. The first member and the second member are configured to be movable to the plasma treatment chamber, the hydrophilization treatment chamber, and the bonding treatment chamber through the conveyance path. The plasma treatment chamber, the hydrophilization treatment chamber, the bonding treatment chamber, and the conveyance path are each controlled to have an internal atmosphere with cleanliness of a predetermined value or less. The plasma treatment chamber is configured to perform plasma treatment on a front surface of each of the first member and the second member. The hydrophilization treatment chamber is configured to perform hydrophilization treatment of attaching moisture to the front surface of each of the first member and the second member after the plasma treatment is performed. The bonding treatment chamber is configured to perform bonding treatment of bonding the first insulating film and the second insulating film performed the hydrophilization treatment, and annealing treatment of heating the first member and the second member to bond the first metal pattern to the second metal pattern.

### BRIEF DESCRIPTION OF THE DRAWINGS

FIG. 1A is a schematic sectional view for illustrating a manufacturing step of a component according to an exemplary embodiment;

FIG. 1B is a schematic sectional view for illustrating a step subsequent to FIG. 1A;

FIG. 1C is a schematic sectional view for illustrating a step subsequent to FIG. 1B;

FIG. 1D is a schematic sectional view for illustrating a step subsequent to FIG. 1C;

FIG. 2A is a schematic sectional view for illustrating a step subsequent to FIG. 1D;

FIG. 2B is an enlarged view of a first member after the step illustrated in FIG. 2A is performed;

FIG. 2C is a schematic sectional view for illustrating a step subsequent to FIG. 2A;

FIG. 2D is a schematic sectional view for illustrating a step subsequent to FIG. 2C;

FIG. 2E is a schematic sectional view for illustrating a step subsequent to FIG. 2D;

FIG. 3 is a schematic configuration diagram of a hybrid bonding equipment;

FIG. 4A is a schematic sectional view for illustrating a manufacturing step of a component according to comparison;

FIG. 4B is a schematic sectional view for illustrating a step subsequent to FIG. 4A;

FIG. 4C is a schematic sectional view for illustrating a step subsequent to FIG. 4B;

FIG. 4D is a schematic sectional view for illustrating a step subsequent to FIG. 4C;

FIG. 5 is a schematic sectional view of a first member according to a first modification; and

FIG. 6 is a schematic sectional view of a component according to a second modification.

### DETAILED DESCRIPTIONS

The method disclosed in PTL 1 and other conventional methods typically use a publicly known damascene method to form an electrode on a front surface of a semiconductor chip and/or a semiconductor wafer to be bonded. This method is performed to form a groove in an insulating film formed on the front surface of the semiconductor chip or the semiconductor wafer to embed metal such as copper in the groove, and remove the metal on the front surface of the insulating film by a chemical mechanical polishing (CMP) method to form an electrode.

In contrast, the hybrid bonding technique needs to perform annealing to perform bonding between electrodes. Thus, volume expansion of metal during the annealing needs to be absorbed by providing a slight gap between the electrodes before the annealing.

However, using the damascene method causes a difficulty in adjustment of height of an electrode with respect to the insulating film, thus causing a difficulty in providing a gap having an appropriate size between electrodes. Additionally, using the CMP method increases manufacturing cost for performing the hybrid bonding.

The present disclosure has been made in view of such a point, and an object of the present disclosure is to provide a method for manufacturing a component, the method being capable of favorably bonding two members at low cost, the component, and a hybrid bonding equipment for the members.

Hereinafter, exemplary embodiments of the present disclosure will be described with reference to the drawings. The description below of a preferred exemplary embodiment is merely exemplary in nature, and is not intended to limit the present disclosure, its applications, or its use.

### EXEMPLARY EMBODIMENT

### Method for manufacturing component formation of first member

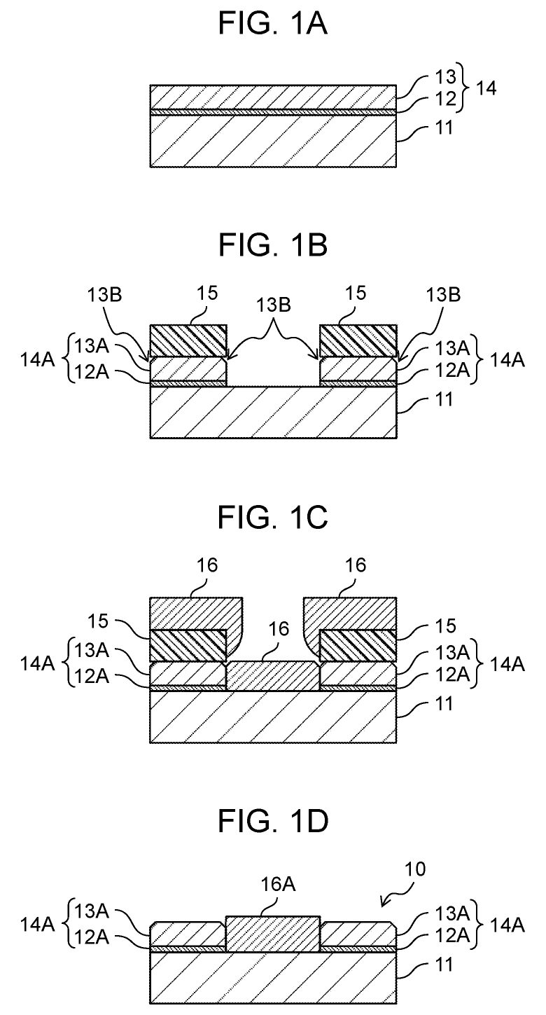

FIG. 1A is a schematic sectional view for illustrating a manufacturing step of a component according to an exemplary embodiment. FIG. 1B is a schematic sectional view for illustrating a step subsequent to FIG. 1A. FIG. 1C is a schematic sectional view for illustrating a step subsequent to FIG. 1B. FIG. 1D is a schematic sectional view for illustrating a step subsequent to FIG. 1C.

As illustrated in FIG. 1A, first semiconductor wafer (first substrate) 11 is prepared. Although a plurality of semiconductor elements is formed on first semiconductor wafer 11, the semiconductor elements are not illustrated. Next, first metal layer 14 is formed on a front surface of first semiconductor wafer 11 (metal layer formation step). First metal layer 14 in the present exemplary embodiment has a thickness of 100 nm, but is not particularly limited to the thickness.

In the present exemplary embodiment, first metal layer 14 has a stacked structure of first seed layer (second layer) 12 and first conductor layer (first layer) 13, and first seed layer 12 is interposed between the front surface of first semiconductor wafer 11 and first conductor layer 13. First seed layer 12 has a stacked structure of a titanium (Ti) film and a copper (Cu) film (neither is illustrated). The titanium film is formed on the front surface of first semiconductor wafer 11, and the copper film is formed on a front surface of the titanium film. The titanium film and the copper film are each formed by a sputtering method. First conductor layer 13 is made of copper and formed by an electrolytic plating method. Besides this, first conductor layer 13 may be formed by another film forming method, such as the sputtering method. First conductor layer 13 may contain a predetermined amount or less of impurities. For example, first conductor layer 13 may contain inevitable impurities mixed during film formation. First conductor layer 13 may be an alloy containing copper as main constituent metal.

Next, resist pattern 15 is formed on a front surface of first metal layer 14 (resist pattern formation step) as illustrated in FIG. 1B. As a method for forming resist pattern 15, publicly known photolithography is used, for example. That is, after a photosensitive resist is applied to the front surface of first metal layer 14, the photosensitive resist is exposed and developed through a photomask pattern (not illustrated) to obtain resist pattern 15. Besides this, resist pattern 15 may be formed by another method such as an imprinting method, for example.

Subsequently, first metal layer 14 is removed to form first metal pattern 14A using resist pattern 15 as an etching mask (metal pattern formation step). The front surface of first semiconductor wafer 11 is exposed at a part from which first metal layer 14 is removed.

First conductor layer 13 and the copper film of first seed layer 12 are removed by wet etching or dry etching. The wet etching is performed using a cupric chloride solution or a ferrous chloride solution, for example. For controlling a shape, a surfactant may be added to an etching solution. The dry etching is performed using a gas containing chlorine, for example. The titanium film of first seed layer 12 is removed by an acidic solution, such as a solution containing hydrofluoric acid. First metal layer 14 may be removed using a physical method such as laser ablation.

When first metal layer 14 is removed by etching in the present exemplary embodiment, a shoulder part of first conductor layer 13 is side-etched to form slope 13B as a chamfer. Slope 13B in the present exemplary embodiment is formed as a C-chamfer, but may be formed as a R-chamfer.

Next, first insulating film 16 is formed on the front surface of first semiconductor wafer 11 with resist pattern 15 remaining (insulating film formation step) as illustrated in FIG. 1C. First insulating film 16 in the present exemplary embodiment is formed by a sputtering method. Besides particularly the sputtering method, a plasma chemical vapor deposition (CVD) method or a room-temperature CVD method may be used, for example.

First insulating film 16 in the present exemplary embodiment has a thickness of 100 nm. First insulating film 16 is not limited to this thickness, but needs to be set to have a thickness equal to or slightly larger than that of first metal layer 14.

As described later, first insulating film 16 formed on the front surface of resist pattern 15 is removed, and first insulating film 16 formed on the front surface of first semiconductor wafer 11 remains as it is. Thus, first insulating film 16 formed on a side surface of resist pattern 15 preferably has poor step coverage or is very thin. Consequently, a sputtering method, in which first insulating film 16 is anisotropically formed and the amount of adhesion to the side surface of resist pattern 15 is reduced, is used more preferably than a CVD method in which first insulating film 16 is isotropically formed on the front surface and the side surface of resist pattern 15.

First insulating film 16 in the present exemplary embodiment is silicon carbonitride (Sin). Besides this, first insulating film 16 may be silicon oxide or silicon nitride. First insulating film 16 may be also another oxide such as hafnium oxide or zirconium oxide. When first insulating film 16 is made of silicon oxide, the silicon oxide can be formed at a low temperature of 400°C or lower by using a CVD method using tetraethoxysilane (TEOS) as a raw material. First insulating film 16 is not limited to an inorganic material, and may be an organic material such as a polymer. Any insulator may be used as long as the insulator has a surface to which a hydroxyl group (-OH) is bonded by a hydrophilization treatment to be described later.

Next, resist pattern 15 is removed using an organic solution such as acetone, methanol, or a developer, as illustrated in FIG. 1D. At this time, first insulating film 16 covering the side surface of resist pattern 15 has poor step coverage or is very thin, so that resist pattern 15 and first insulating film 16 covering the resist pattern are removed at the same time (resist lift-off step). Meanwhile, first insulating film 16 formed on the front surface of first semiconductor wafer 11 remains as it is.

At this time, first metal pattern 14A and first insulating film 16A provided surrounding a side surface of first metal pattern 14A are formed on the front surface of first semiconductor wafer 11. Multiple first metal patterns 14A are periodically provided on the front surface of first semiconductor wafer 11. One first metal pattern 14A is electrically connected to one or more semiconductor elements formed on first semiconductor wafer 11. That is, first metal pattern 14A functions as an external connection electrode (referred to also as a pad electrode) in a semiconductor chip obtained by dividing first semiconductor wafer 11. First semiconductor wafer 11 in the state illustrated in FIG. 1D may be referred to as first member 10 in the following description.

### Method for manufacturing component (formation of component) and configuration of hybrid bonding equipment

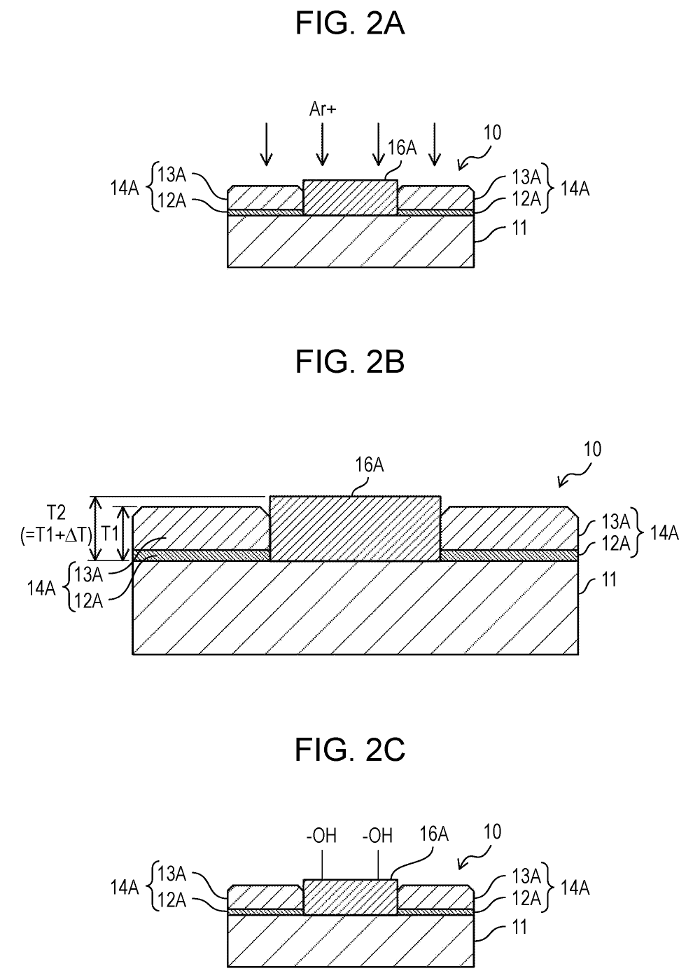

FIG. 2A is a schematic sectional view for illustrating a step subsequent to FIG. 1D. FIG. 2B is an enlarged view of a first member after the step illustrated in FIG. 2A is performed. FIG. 2C is a schematic sectional view for illustrating a step subsequent to FIG. 2A.

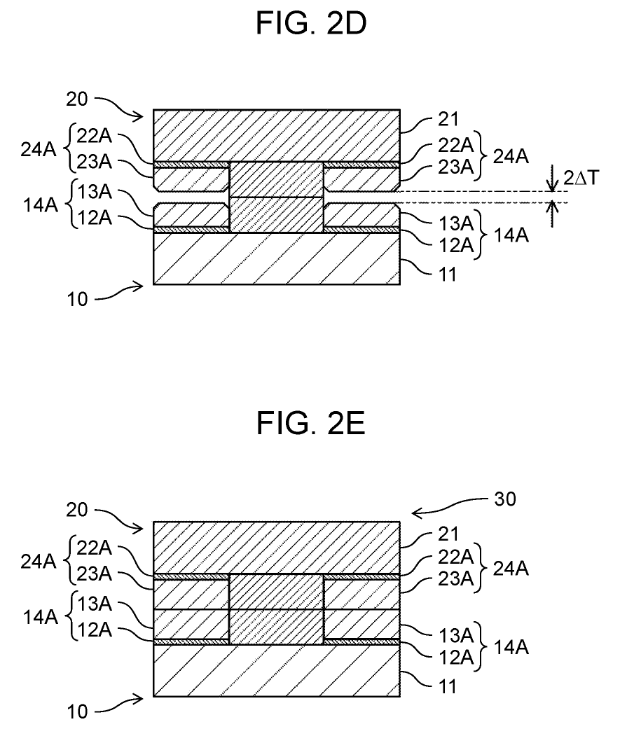

FIG. 2D is a schematic sectional view for illustrating a step subsequent to FIG. 2C. FIG. 2E is a schematic sectional view for illustrating a step subsequent to FIG. 2D. FIG. 3 is a schematic configuration diagram of a hybrid bonding equipment.

After the resist lift-off step illustrated in FIG. 1D is performed, the steps illustrated in FIG. 2A and FIGS. 2C to 2E are sequentially performed. These steps are performed by hybrid bonding equipment 100 illustrated in FIG. 3. A configuration of hybrid bonding equipment 100 will also be described below in accordance with description of each step.

After the resist lift-off step is performed, first member 10 is set in loading and unloading chamber 120 of hybrid bonding equipment 100.

Hybrid bonding equipment 100 includes housing 110 that is internally provided with loading and unloading chamber 120, plasma treatment chamber 130, hydrophilization treatment chamber 140, bonding treatment chamber 150, and conveyance chamber 160. loading and unloading chamber 120, plasma treatment chamber 130, hydrophilization treatment chamber 140, and bonding treatment chamber 150 are each connected to conveyance chamber 160 through conveyance path 170. First member 10 set in loading and unloading chamber 120 is configured to be movable to plasma treatment chamber 130, hydrophilization treatment chamber 140, bonding treatment chamber 150, and loading and unloading chamber 120 through conveyance chamber 160 by a conveyance mechanism (not illustrated).

Housing 110 is controlled to have an internal atmosphere with cleanliness of a predetermined value or less, for example, a cleanliness of 100 or less. Similarly, loading and unloading chamber 120, plasma treatment chamber 130, hydrophilization treatment chamber 140, bonding treatment chamber 150, conveyance chamber 160, and conveyance path 170 are each also controlled to have an internal atmosphere with cleanliness of a predetermined value or less. Housing 110 can be eliminated. However, loading and unloading chamber 120, plasma treatment chamber 130, hydrophilization treatment chamber 140, bonding treatment chamber 150, conveyance chamber 160, and conveyance path 170 are each required to be controlled to have an internal atmosphere with cleanliness of a predetermined value or less.

First member 10 set in loading and unloading chamber 120 is conveyed from loading and unloading chamber 120 to plasma treatment chamber 130 through conveyance path 170 and conveyance chamber 160 by the conveyance mechanism (not illustrated).

Plasma treatment chamber 130 is evacuated by a vacuum pump (not illustrated) to have a degree of vacuum less than or equal to a predetermined value. Plasma treatment chamber 130 is internally provided with a stage, an upper electrode, and a gas introduction port (each is not illustrated). First member 10 transferred from conveyance path 170 to plasma treatment chamber 130 is placed on the stage. When voltage is applied between the stage and the upper electrode after argon (Are) gas is introduced from the gas introduction port, argon plasma is generated between the stage and the upper electrode. The upper electrode is a positive electrode, so that argon ions as positive ions are incident on a front surface of first member 10 on the stage, that is, incident on a front surface of each of first metal pattern 14A and first insulating film 16A (activation step) as illustrated in FIG. 2A. Irradiation with the argon ions removes an oxide of copper from a front surface of first conductor layer 13A to expose a clean surface of copper. The front surface of first insulating film 16A is also activated, and is likely to be bonded to a hydroxyl group by the subsequent hydrophilization treatment.

Although first insulating film 16A is bonded to second insulating film 26A (see FIG. 2D) in a bonding step described later, the bonding step fails to be performed well when using first metal pattern 14A having a thicker thickness with respect to the front surface of first semiconductor wafer 11 than first insulating film 16A. Thus, the activation step is performed to simultaneously adjust a thickness of each of first metal pattern 14A and first insulating film 16A using irradiation with argon ions. Specifically, argon plasma generation conditions, that is, pressure in the plasma treatment chamber 130, voltage between the stage and the upper electrode, the plasma treatment time, and the like are set to allow first insulating film 16A to have thickness T2 thicker than thickness T1 of first metal pattern 14A as illustrated in FIG. 2B. Difference ΔT between thicknesses T1 and T2 is about several nm to several tens nm. Additionally, a gas type of plasma is not limited to argon as long as activation of the front surface of first insulating film 16A, cleaning of the front surface of first metal pattern 14A, and adjustment of the thickness of each of first metal pattern 14A and first insulating film 16A are appropriately performed. For example, nitrogen or other inert gas may be used. Alternatively, any one of oxygen, hydrogen, chlorine, and fluorine may be used. Alternatively, a plurality of kinds of these gases including argon may be mixed.

Next, first member 10 is conveyed to hydrophilization treatment chamber 140 through conveyance path 170 and conveyance chamber 160. Hydrophilization treatment chamber 140 is internally provided with a rotary table and a pure water introduction nozzle (neither is illustrated).

First member 10 having been conveyed to hydrophilization treatment chamber 140 is placed on the rotary table. The pure water introduction nozzle injects pure water toward the front surface of first member 10 before or during rotation of the rotary table to allow moisture to adhere to the front surface of first member 10 (hydrophilization step). After the injection of the pure water is finished, the rotary table is rotated to remove unnecessary moisture remaining on the front surface of first member 10.

After the hydrophilization treatment is performed, a hydroxyl group is bonded to the front surface of first insulating film 16A in the activation step to cause the front surface of first insulating film 16A to be hydrophilic as illustrated in FIG. 2C. The hydroxyl group has oxygen having a valence of two, one of which is not bonded to another atom to form a dangling bond. In the following description, the activation step and the hydrophilization step may be collectively referred to as a surface treatment step.

Next, first member 10 is conveyed to bonding treatment chamber 150 through conveyance path 170 and conveyance chamber 160. As illustrated in FIG. 3, bonding treatment chamber 150 includes alignment mechanism 151, pressurization mechanism 152, and heating mechanism 153. Although not illustrated, bonding treatment chamber 150 includes a stage and a gripping mechanism that grips a semiconductor wafer, a chip, or a substrate. The gripping mechanism includes a rotation mechanism that rotates the semiconductor wafer, the chip, or the substrate about an axis parallel to a front surface of each of the semiconductor wafer, the chip, or the substrate, and a movement mechanism that moves the gripped semiconductor wafer, the chip, or the substrate in a direction perpendicular to a direction parallel to the stage.

First member 10 having been conveyed to bonding treatment chamber 150 is placed on the stage. Second member 20 (see FIG. 2D) is also conveyed to bonding treatment chamber 150, and second member 20 is gripped by the gripping mechanism.

Second member 20 is similar in structure to first member 10. Specifically, second member 20 includes second semiconductor wafer (second substrate) 21, second metal pattern 24A formed on a front surface of second semiconductor wafer 21, and second insulating film 26A provided surrounding a side surface of second metal pattern 24A. Second metal pattern 24A and second insulating film 26A in the present exemplary embodiment are identical in materials and formation methods to first metal pattern 14A and first insulating film 16A described above, respectively. However, second seed layer 22A, second conductor layer (third layer) 23A, and second insulating film 26A may be different in thickness from first seed layer 12A, first conductor layer 13A, and first insulating film 16A, respectively. As with first member 10, the activation step and the hydrophilization step are performed on second member 20.

In this state, the gripping mechanism is operated to cause a front surface of second member 20 to face the front surface of first member 10 as illustrated in FIG. 2D. Then, alignment mechanism 151 aligns second member 20 with respect to first member 10 to cause first metal pattern 14A to overlap with second metal pattern 24A when viewed from above the stage. For the alignment, first metal pattern 14A and second metal pattern 24A are optically aligned by irradiating second semiconductor wafer 21 with transparent light from above a back surface of second member 20.

Next, the front surface of first member 10 and the front surface of second member 20 are brought into contact with each other as illustrated in FIG. 2D. While pressurization mechanism 152 applies a predetermined load to second member 20, the front surface of first insulating film 16A is bonded to a front surface of second insulating film 26A (bonding step). In the bonding step, temperature of the stage, in other words, temperature of each of first member 10 and second member 20 is room temperature, but the stage may be heated by heating mechanism 153 as necessary. At this time, the temperature of the stage is set to less than or equal to 200°C.

In the bonding step, hydroxyl groups bonded to the front surfaces of first insulating film 16A and second insulating film 26A are chemically bonded to each other to generate oxygen and water. At that time, a dangling bond is generated on each of the front surfaces of first insulating film 16A and second insulating film 26A. The dangling bond on the front surface of first insulating film 16A and the dangling bond on the front surface of second insulating film 26A are covalently bonded to each other to bond first insulating film 16A to second insulating film 26A.

Subsequently, while pressurization mechanism 152 applies a load to second member 20, heating mechanism 153 heats the stage (annealing step). A load in the annealing step is set to a value equal to or larger than a load in the bonding step. A heating temperature in the annealing step is set to a temperature at which interdiffusion of copper between first conductor layer 13A and second conductor layer 23A proceeds to have a sufficient bonding strength between the layers. The heating temperature in the annealing step is also set to a temperature that does not thermally damage a semiconductor element and internal wiring (neither is illustrated) formed on each of first semiconductor wafer 11 and second semiconductor wafer 21. In consideration of these, the heating temperature in the annealing step is preferably from 200°C to 400°C inclusive.

As illustrated in FIG. 2D, when the front surface of first insulating film 16A is bonded to the front surface of second insulating film 26A at room temperature, a gap of about 2ΔT exists between the front surface of first conductor layer 13A and the front surface of second conductor layer 23A. Meanwhile, when first member 10 and second member 20 are heated in the annealing step, first conductor layer 13A and second conductor layer 23A are thermally expanded.

First conductor layer 13A and second conductor layer 23A are each made of copper. Each of first conductor layer 13A and second conductor layer 23A has a thickness of about 100 nm. Copper has a linear expansion coefficient of 17.7 × 10⁻⁶/K, so that each of first conductor layer 13A and second conductor layer 23A increases in thickness by about 5.3 nm when the annealing step is performed at a temperature higher by about 300°C than room temperature. When ΔT is set to be smaller than this value, the front surface of first conductor layer 13A and the front surface of second conductor layer 23A are brought into contact with each other during annealing to cause interdiffusion of copper to proceed at an interface between the layers, thereby metal-bonding first conductor layer 13A to second conductor layer 23A.

After the annealing step is performed, component 30 is finally obtained in which first member 10 and second member 20 are subjected to hybrid bonding as illustrated in FIG. 2E. That is, first metal pattern 14A and second metal pattern 24A are aligned and then metal-bonded to each other, and first insulating film 16A is bonded to second insulating film 26A. Consequently, the semiconductor element formed on first semiconductor wafer 11 is electrically connected to the semiconductor element formed on second semiconductor wafer 21 through first metal pattern 14A and second metal pattern 24A.

Component 30 is conveyed from bonding treatment chamber 150 to loading and unloading chamber 120 through conveyance path 170 and conveyance chamber 160, and then taken out to the outside of hybrid bonding equipment 100.

### Effects and the like

As described above, the method for manufacturing component 30 according to the present exemplary embodiment includes at least the metal layer formation step, the resist pattern formation step, the metal pattern formation step, the insulating film formation step, and the resist lift-off step. The method for manufacturing component 30 also includes the second member preparation step, the surface treatment step, the bonding step, and the annealing step. Component 30 is obtained by bonding first member 10 to second member 20.

The metal layer formation step is performed to form first metal layer 14 on the front surface of first semiconductor wafer (first substrate) 11.

The resist pattern formation step is performed to form resist pattern 15 on the front surface of first metal layer 14.

The metal pattern formation step is performed to form first metal pattern 14A by removing first metal layer 14 using resist pattern 15 as a mask.

The insulating film formation step is performed to form first insulating film 16 on the front surface of first semiconductor wafer 11 with resist pattern 15 left on the front surface of first metal pattern 14A.

The resist lift-off step is performed to remove first insulating film 16 covering resist pattern 15 together with resist pattern 15, thereby obtaining first member 10 with a front surface provided with first metal pattern 14A and first insulating film 16A provided covering a side surface of first metal pattern 14A.

The second member preparation step is performed to prepare second member 20 in which second metal pattern 24A and second insulating film 26A provided covering a side surface of second metal pattern 24A are formed on a front surface of second semiconductor wafer (second substrate) 21.

The surface treatment step is performed to perform predetermined treatment on the front surface of first member 10 after the resist lift-off step is performed and on the front surface of second member 20.

The bonding step is performed, after the surface treatment step is performed, to align first member 10 and second member 20 such that the front surface of first member 10 and the front surface of second member 20 face each other, and to bond first insulating film 16A and second insulating film 26A.

The annealing step is performed to bond first metal pattern 14A to second metal pattern 24A by heating first member 10 and second member 20 to a predetermined temperature after the surface treatment step is performed.

The surface treatment step includes the activation step of performing the plasma treatment on the front surface of each of first member 10 and second member 20, and the hydrophilization treatment of attaching moisture to the front surface of each of first member 10 and second member 20 following the activation step.

The present exemplary embodiment enables two members, each with a front surface provided with an electrode pattern and an insulating film, that is, first member 10 and second member 20, to be bonded to each other at low cost and favorably. Then, component 30 obtained by bonding first member 10 to second member 20 can be improved in a manufacturing yield and reliability.

More specifically, the damascene method described above, that is, the CMP method with high cost does not need to be used when hybrid bonding between first member 10 and second member 20 is performed, so that bonding cost between first member 10 and second member 20 can be reduced.

When first member 10 is bonded to second member 20 by the hybrid bonding, bonding strength between them can be enhanced. Consequently, the manufacturing yield of component 30 and connection reliability of wiring in component 30 can be improved.

According to the present exemplary embodiment, first seed layer (second layer) 12 is not provided between the side surface of first metal pattern 14A and a side surface of first insulating film 16A, and second seed layer 22A is not provided between a side surface of second metal pattern 24A and a side surface of second insulating film 26A. Consequently, first seed layer (second layer) 12 and second seed layer 22A can be prevented from oxidation and reaction with a chemical solution or the like. This will be further described.

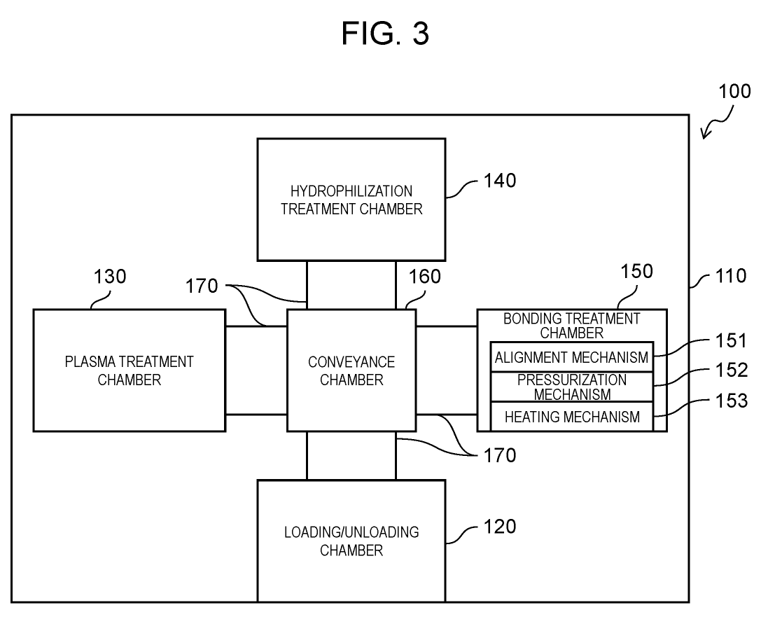

FIG. 4A is a schematic sectional view for illustrating a manufacturing step of a component according to comparison. FIG. 4B is a schematic sectional view for illustrating a step subsequent to FIG. 4A. FIG. 4C is a schematic sectional view for illustrating a step subsequent to FIG. 4B. FIG. 4D is a schematic sectional view for illustrating a step subsequent to FIG. 4C.

The steps illustrated in FIGS. 4A to 4D are until first member 10 is obtained using the damascene method, and are different from the steps illustrated in FIGS. 1A to 1D in the following points.

A conventional method according to the comparison includes forming first insulating film 16 on the front surface of first semiconductor wafer 11 as illustrated in FIG. 4A, and then includes forming a resist pattern (not illustrated) on the front surface of first insulating film 16 by photolithography, and removing first insulating film 16 using a resist pattern as a mask to form first insulating film 16A subjected to patterning, as illustrated in FIG. 4B.

Next, first metal layer 14 is formed on the front surface of first semiconductor wafer 11 provided with first insulating film 16A as illustrated in FIG. 4C. FIG. 4C reveals that first metal layer 14 is also formed on a side surface of first insulating film 16A in the formation. Specifically, the side surface of first insulating film 16A is covered with first seed layer 12, and a front surface of first seed layer 12 is covered with first conductor layer 13.

Finally, first metal layer 14 is removed by the CMP method to cause the front surface of first metal pattern 14A to be slightly lower than the front surface of first insulating film 16A, thereby obtaining first member 10 as illustrated in FIG. 4D.

However, first member 10 illustrated in FIG. 4D includes first seed layer 12B interposed between a side surface of first conductor layer 13A and the side surface of first insulating film 16A. When first member 10 is cleaned after the CMP, a titanium film may be etched or oxidized due to first seed layer 12B exposed to a cleaning liquid. When first seed layer 12B is exposed to argon plasma and damaged in the subsequent activation step, the titanium film of first seed layer 12B is likely to be oxidized until first member 10 is conveyed to the next step or in the hydrophilization step. Although not illustrated, the same problem occurs even when second member 20 is produced by a similar method.

When first seed layer 12B is oxidized or etched as described above, adhesion between first conductor layer 13A and first seed layer 12B deteriorates. Thus, connection reliability between first metal pattern 14A and second metal pattern 24A may deteriorate in the annealing step to be performed subsequently. When first seed layer 12B retreats, a bonding area between first metal pattern 14A and second metal pattern 24A decreases, which may lead to a decrease in bonding strength.

In contrast, the present exemplary embodiment includes first seed layer 12A that is interposed only between the front surface of first semiconductor wafer 11 and the back surface of first conductor layer 13A, so that first seed layer 12A may not be oxidized or etched in the activation step or the hydrophilization step described above. Consequently, bonding strength between first metal pattern 14A and second metal pattern 24A can be prevented from deteriorating, thus enhancing the connection reliability.

When first member 10 is produced using the damascene method, a polishing rate of first conductor layer 13 by the CMP cannot be made too low to shorten time of a step, thereby causing a difficulty in appropriately adjusting height of first conductor layer 13A. In other words, controlling the ΔT to a desired value becomes difficult.

In contrast, the present exemplary embodiment facilitates adjustment of height of first conductor layer 13A by appropriately setting generation conditions of the argon plasma and plasma treatment time. Appropriate setting of a material of first conductor layer 13A and a material of first insulating film 16A also facilitates the adjustment of height of first conductor layer 13A.

First metal pattern 14A usually has a size of about several tens mm to hundred and several tens me in a direction parallel to the front surface of first semiconductor wafer 11. However, this size may cause dishing, that is, a recess to be generated in the front surface of first conductor layer 13A due to polishing first conductor layer 13 by the CMP. The dishing formed in the front surface of first conductor layer 13A and having a depth more than a predetermined value may cause a connection failure between first metal pattern 14A and second metal pattern 24A in the annealing step to be performed later.

In contrast, the present exemplary embodiment does not use the CMP method, so that dishing does not occur in the front surface of first conductor layer 13A, thereby preventing connection failure between first metal pattern 14A and second metal pattern 24A.

The metal pattern formation step may be performed to remove first metal layer 14 using any one of wet etching, laser ablation, and plasma etching.

The resist lift-off step may be performed to remove first insulating film 16 together with resist pattern 15 using a chemical solution of any one of an organic solvent, a developer, and an acidic solution.

Each of the metal pattern formation step and the resist lift-off step can be performed by a publicly known method, so that an increase in manufacturing cost of component 30 can be suppressed.

Any one or more kinds of inert gas, oxygen, hydrogen, chlorine, and fluorine may be used as gas in the plasma treatment in the activation step. The activation step is only required to appropriately remove the oxide or the like on the front surface of first conductor layer 13A, activate the front surface of first insulating film 16A, and appropriately adjust difference ΔT of height between first metal pattern 14A and first insulating film 16A.

The bonding step is preferably performed at a temperature of less than or equal to 200°C. Consequently, first insulating film 16A can be bonded to second insulating film 26A while volume expansion of first conductor layer 13A and second conductor layer 23A is suppressed. Appropriate setting of a load to be applied by pressurization mechanism 152 allows the front surface of first conductor layer 13A and the front surface of second conductor layer 23A to be in contact with each other at the start of the bonding step.

First insulating film 16A may be made of an inorganic material or an organic material. When first insulating film 16A is made of an inorganic material, the inorganic material may be any one selected from among silicon oxide, silicon nitride, silicon carbonitride, zirconia oxide, and hafnium oxide. After the activation step and the hydrophilization step are performed, a predetermined amount or more of hydroxyl groups having dangling bonds is only required to be bonded to the front surface of first insulating film 16A.

When first insulating film 16 is made of a polymer of an organic material, the polymer is preferably formed by a spin coating method. When a polymer film is formed by a spin coating method, a liquid polymer is dropped onto the front surface of first semiconductor wafer 11 placed on a rotary table, and the rotary table is rotated. This method enables forming a uniform polymer film. Thickness of the polymer film can be adjusted by adjusting rotation speed of the rotary table.

In general, when first insulating film 16 is formed by the CVD method or the sputtering method, many particles each having a size of about several μm to several hundred μm often adhere to the front surface of first insulating film 16. Unfortunately, such particles adhering to the front surface of first insulating film 16A cause a bonding failure between first insulating film 16A and second insulating film 26A in the bonding step.

In contrast, the spin coating method causes a frequency of attachment of particles of the above-described size to the front surface of first insulating film 16 to be significantly reduced as compared with the CVD method or the sputtering method. Thus, first insulating film 16 formed as the polymer film enables not only reduction in bonding failure between first insulating film 16A and second insulating film 26A can be reduced, but also increase in bonding strength between the first insulating film and the second insulating film.

Then, appropriate adjustment of rotation speed of the rotary table and viscosity of the liquid polymer enables sufficient reduction in thickness of the polymer film attached to the side surface of first metal pattern 14A. Consequently, first insulating film 16 covering resist pattern 15 together with resist pattern 15 can be reliably removed in the resist lift-off step. The same applies to formation of second insulating film 26A.

Second insulating film 26A is preferably identical in material to first insulating film 16A. Consequently, first member 10 and second member 20 can be treated under the same conditions in the activation step and the hydrophilization step, thus simplifying a manufacturing step of component 30. However, second insulating film 26A may be different in material from first insulating film 16A when a predetermined amount or more of hydroxyl groups having dangling bonds is bonded to the front surfaces of first insulating film 16A and second insulating film 26A after the activation step and the hydrophilization step are performed.

First metal pattern 14A includes first conductor layer (first layer) 13 exposed on the front surface of first metal pattern 14A. First conductor layer 13 is preferably made of copper or an alloy mainly composed of copper. As described above, first metal pattern 14A is an external connection electrode for a semiconductor element formed on first semiconductor wafer 11. Thus, when first conductor layer 13 as a main part of first metal pattern 14A is made of copper or the alloy mainly composed of copper, first metal pattern 14A can be reduced in electrical resistance.

First metal layer 14 further includes first seed layer (second layer) 12 provided between first conductor layer 13 and first semiconductor wafer 11. Providing first seed layer 12 enables first conductor layer 13 to be formed by electrolytic plating. Consequently, a deposition rate of first conductor layer 13 can be increased, and manufacturing time and eventually manufacturing cost of component 30 can be reduced as compared with other methods, such as a sputtering method and an electroless plating method.

Second metal pattern 24A includes second conductor layer (third layer) 23A exposed on the front surface of second metal pattern 24A. Second conductor layer 23A is preferably identical in material to first conductor layer 13. This configuration allows mutual diffusion of constituent metals to easily proceed in the annealing step because first conductor layer 13A and second conductor layer 23A are identical in constituent metal. Consequently, bonding strength between first conductor layer 13A and second conductor layer 23A can be increased. Additionally, an unintended metal compound or alloy can be prevented from being formed at an interface between first conductor layer 13A and second conductor layer 23A, and connection resistance between first metal pattern 14A and second metal pattern 24A also can be reduced. Then, the connection reliability between first metal pattern 14A and second metal pattern 24A can be enhanced.

First metal pattern 14A after the activation step is performed preferably has a thinner thickness than first insulating film 16A. Similarly, second metal pattern 24A after the activation step is performed preferably has a thinner thickness than second insulating film 26A. In general, first insulating film 16A and second insulating film 26A each have a lower thermal expansion coefficient than copper constituting first conductor layer 13A and second conductor layer 23A. Thus, first metal pattern 14A and second metal pattern 24A, which are each defined to have a thickness as described above, enable preventing an occurrence of contact failure between the front surface of first insulating film 16A and the front surface of second insulating film 26A due to volume expansion of first conductor layer 13A and second conductor layer 23A in the bonding step.

First metal pattern 14A after the metal pattern formation step is performed preferably has a shape in which the front surface has corners chamfered, and the corners are each slope 13B in sectional view. Similarly, second metal pattern 24A after the metal pattern formation step is performed preferably has a shape in which the front surface has corners chamfered, and the corners are each identical in shape to slope 13B in sectional view.

This configuration allows a recess recessed inward to be formed at a connection part between the side surface of first metal pattern 14A and the side surface of resist pattern 15 in the insulating film formation step, thus reducing covering of first insulating film 16 near the connection part. That is, first insulating film 16 is likely to have poor step coverage near this connection part. Additionally, first insulating film 16 has a much thinner film thickness than other parts. Consequently, first insulating film 16 covering resist pattern 15 can be easily removed in the resist lift-off step. The same applies to the formation of second insulating film 26A.

First metal pattern 14A and second metal pattern 24A each have a shape in which the front surface has corners chamfered, so that a gap can be formed in a part where the corners of first conductor layer 13A and second conductor layer 23A face each other in the annealing step. Consequently, excessive pressure due to volume expansion can be prevented from being applied to the corners of each of first conductor layer 13A and second conductor layer 23A, so that the connection reliability between first metal pattern 14A and second metal pattern 24A can be improved.

Component 30 according to the present exemplary embodiment is obtained by bonding first member 10 to second member 20.

First member 10 includes first semiconductor wafer 11 with a front surface provided with first metal pattern 14A and first insulating film 16A provided covering the side surface of first metal pattern 14A.

Second member 20 includes second semiconductor wafer 21 with a front surface provided with second metal pattern 24A and second insulating film 26A provided covering the side surface of second metal pattern 24A.

First insulating film 16A is bonded to second insulating film 26A, and first metal pattern 14A is bonded to second metal pattern 24A.

First metal pattern 14A at least includes first conductor layer 13A exposed on the front surface of first metal pattern 14A, and first seed layer 12A provided between first conductor layer 13A and first semiconductor wafer 11.

First seed layer 12A is not provided between the side surface of first metal pattern 14A and the side surface of first insulating film 16A.

Second metal pattern 24A includes second conductor layer 23A exposed on the front surface of second metal pattern 24A, and second seed layer 22A provided between second conductor layer 23A and second semiconductor wafer 21.

Second seed layer 22A is not provided between the side surface of second metal pattern 24A and the side surface of second insulating film 26A.

According to the present exemplary embodiment, first member 10 is favorably bonded to second member 20 at low cost, so that component 30 with high reliability can be implemented. Then, first metal pattern 14A is connected to second metal pattern 24A by metal bonding, so that the connection resistance between first metal pattern 14A and second metal pattern 24A can be reduced. The connection reliability therebetween also can be improved.

Multiple first metal patterns 14A are provided on the front surface of first semiconductor wafer 11 at predetermined intervals. Multiple second metal patterns 24A are provided on the front surface of second semiconductor wafer 21 at predetermined intervals.

First insulating film 16A is formed on the front surface of first semiconductor wafer 11 while filling gaps between corresponding multiple first metal patterns 14A. Second insulating film 26A is formed on the front surface of second semiconductor wafer 21 while filling gaps between corresponding multiple second metal patterns 24A.

This configuration enables component 30 to be operated as an electronic circuit by increasing the number of electrical connection points between multiple semiconductor elements formed on first semiconductor wafer 11 and corresponding multiple semiconductor elements formed on second semiconductor wafer 21. Additionally, connection resistance at each connection point can be reduced, and connection reliability at each connection point can be improved.

First metal pattern 14A is preferably equal in size to second metal pattern 24A in a direction along a bonding interface between first semiconductor wafer 11 and second semiconductor wafer 21. This configuration enables maximizing a size of first metal pattern 14A and a bonding area between first metal pattern 14A and second metal pattern 24A, thus improving reliability of component 30. From a similar reason, first metal pattern 14A is preferably equal in an arrangement pitch to second metal pattern 24A.

Hybrid bonding equipment 100 according to the present exemplary embodiment is used for bonding first member 10 to second member 20.

First member 10 includes first semiconductor wafer 11 with a front surface provided with first metal pattern 14A and first insulating film 16A provided covering the side surface of first metal pattern 14A. Second member 20 includes second semiconductor wafer 21 with a front surface provided with second metal pattern 24A and second insulating film 26A provided covering the side surface of second metal pattern 24A.

Hybrid bonding equipment 100 includes at least plasma treatment chamber 130, hydrophilization treatment chamber 140, bonding treatment chamber 150, conveyance chamber 160, loading and unloading chamber 120, and conveyance path 170.

Plasma treatment chamber 130, hydrophilization treatment chamber 140, bonding treatment chamber 150, and loading and unloading chamber 120 are each connected to conveyance chamber 160 through conveyance path 170.

Hybrid bonding equipment 100 includes first member 10 and second member 20 that are configured to be movable to plasma treatment chamber 130, hydrophilization treatment chamber 140, bonding treatment chamber 150, and loading and unloading chamber 120 through conveyance chamber 160.

Plasma treatment chamber 130, hydrophilization treatment chamber 140, bonding treatment chamber 150, conveyance chamber 160, and conveyance path 170 are each controlled to have an internal atmosphere with cleanliness of a predetermined value or less.

Plasma treatment chamber 130 is configured to perform plasma treatment on the front surface of each of first member 10 and second member 20.

Hydrophilization treatment chamber 140 is configured to perform hydrophilization treatment of attaching moisture to the front surface of each of first member 10 and second member 20 after the plasma treatment is performed.

The bonding treatment chamber is configured to perform bonding treatment of bonding first insulating film 16A to second insulating film 26A after the hydrophilization treatment is performed, and annealing treatment of heating first member 10 and second member 20 to bond first metal pattern 14A to second metal pattern 24A.

Hybrid bonding equipment 100 configured as described above enables a series of treatment from the activation step to the annealing step to be continuously performed while maintaining a cleanliness of a predetermined value or less. Consequently, adhesion of particles and the like to the front surface of each of first member 10 and second member 20 after the activation treatment is performed is suppressed, so that bonding failure between first member 10 and second member 20 can be reduced to suppress deterioration in bonding strength. As a result, component 30 obtained by bonding first member 10 to second member 20 can be improved in a manufacturing yield and reliability.

A state of the front surface of each of first member 10 and second member 20 after the activation treatment is performed may change due to adsorption of moisture in the atmosphere, for example. In consideration of this change, standby time from after the end of each step to before the start of a next step is preferably managed as appropriate from after the end of the activation treatment to before the start of the bonding treatment.

### First modification

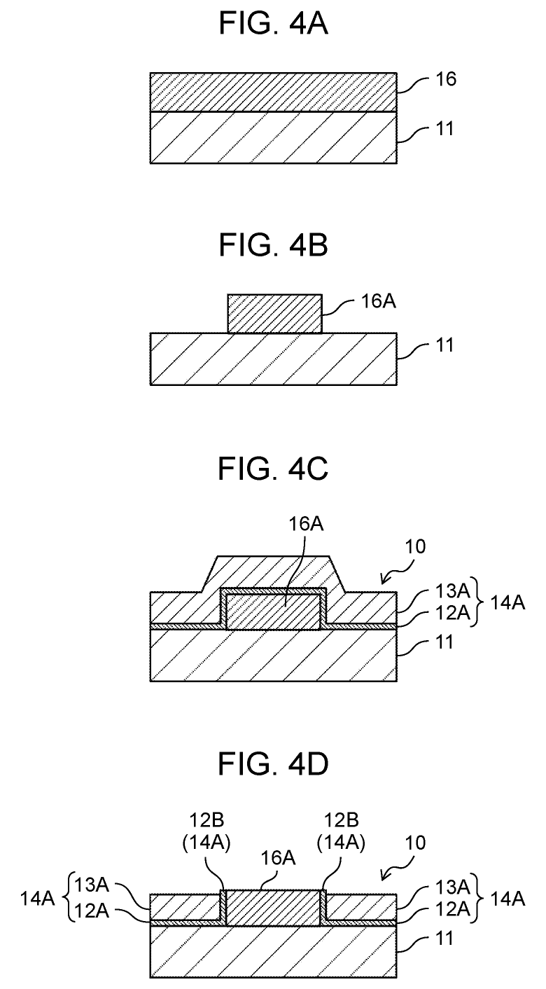

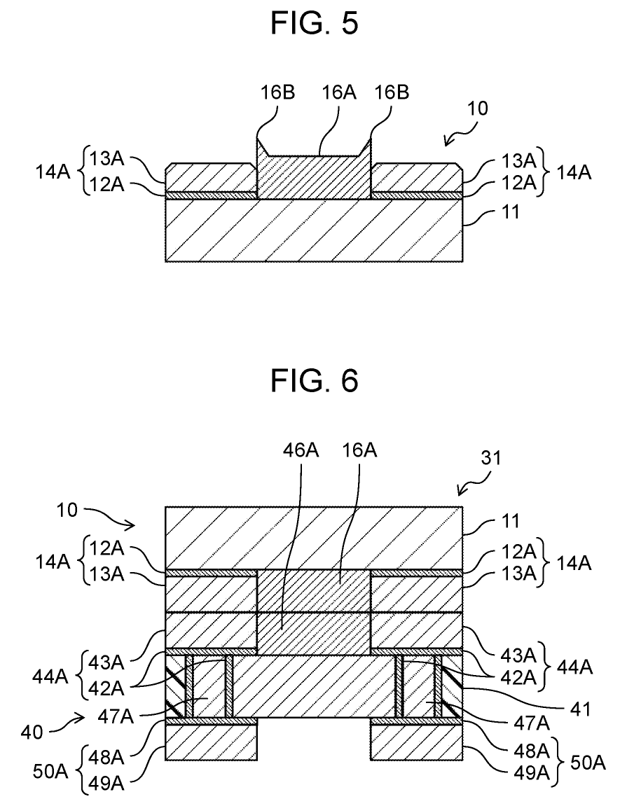

FIG. 5 is a schematic sectional view of a first member according to a first modification. Specifically, FIG. 5 illustrates first member 10 before the bonding treatment is performed. For convenience of description, FIG. 5 and FIG. 6 to be described later each denote parts similar to those in the exemplary embodiment with the same reference numerals, and details of the parts will not be described.

First member 10 illustrated in FIG. 5 is different from first member 10 of the exemplary embodiment illustrated in FIG. 1D in that protrusion 16B is provided protruding from a corner of the front surface of first insulating film 16A.

Protrusion 16B can be formed by appropriately setting a film thickness of first insulating film 16, shedding conditions of a developer or the like in the resist lift-off step, and the shape of slope 13B provided at the corner of the front surface of first conductor layer 13A, for example.

As described above, the bonding step is performed to optically align first metal pattern 14A and second metal pattern 24A by irradiating second semiconductor wafer 21 with transparent light from above the back surface of second member 20. Providing protrusion 16B at the corner of the front surface of first insulating film 16A enables reliable detection of a position of protrusion 16B when optical alignment is performed, thus improving alignment accuracy between first metal pattern 14A and second metal pattern 24A. As a result, bonding failure between first metal pattern 14A and second metal pattern 24A can be reduced, thus improving the manufacturing yield and reliability of component 30.

### Second modification

FIG. 6 is a schematic sectional view of a component according to a second modification.

Second member 40 of component 31 illustrated in FIG. 6 is different from second member 20 illustrated in FIG. 2E in that wiring substrate (second substrate) 41 is used instead of second semiconductor wafer 21.

Wiring substrate 41 has a front surface provided with not only multiple second metal patterns 44A at a predetermined arrangement pitch, but also second insulating film 46A covering a side surface of second metal patterns 44A. Wiring substrate 41 has a back surface provided with third metal pattern 50A including third seed layer 48A and third conductor layer 49A, and second metal pattern 44A is connected to third metal pattern 50A with second seed layer 42A and fourth conductor layer 47A interposed therebetween.

Examples of wiring substrate 41 include a glass substrate, a resin substrate, and a ceramic substrate. Besides this, wiring substrate 41 may be a semiconductor substrate provided with no semiconductor element. When light is emitted from above the back surface of wiring substrate 41 to optically align first metal pattern 14A and second metal pattern 44A, wiring substrate 41 needs to be made of a material that transmits light.

Second seed layer 42A and second conductor layer 43A are identical in material to second seed layer 22A and second conductor layer 23A, respectively. Third seed layer 48A is also preferably identical in material to second seed layer 22A, and third conductor layer 49A and fourth conductor layer 47A are also each preferably identical in material to second conductor layer 23A. Consequently, the seed layer and the conductor layer each can be formed by the same equipment and method.

From a reason similar to that as described in the exemplary embodiment, first metal pattern 14A is preferably equal in size to second metal pattern 44A in a direction along a bonding interface between wiring substrate 41 and first semiconductor wafer 11. Then, first metal pattern 14A is preferably equal in an arrangement pitch to second metal pattern 44A.

Third metal pattern 50A functions as an external connection electrode of component 31. Each of fourth conductor layer 47A and second seed layer covering the fourth conductor layer functions as a via that electrically connects second metal pattern 44A to third metal pattern 50A.

Component 31 may be obtained by bonding not only semiconductor wafers each having a front surface provided with a metal pattern and an insulating film to each other, but also dissimilar substrates each having a front surface provided with a metal pattern and an insulating film to each other as shown in the present modification. Consequently, a semiconductor device including an interconnection with a short wiring distance from a circuit substrate or the like and high density can be implemented. Additionally, second member 40 including wiring substrate 41 can be favorably bonded to first member 10 including first semiconductor wafer 11 at low cost. Then, component 31 obtained by bonding first member 10 to second member 40 can be improved in a manufacturing yield and reliability.

Second member 40 may include second metal pattern 44A that is not connected to third metal pattern 50A with fourth conductor layer 47A or the like interposed therebetween. Some of second metal patterns 44A may be connected to corresponding third metal patterns 50A with corresponding fourth conductor layers 47A or the like interposed therebetween.

### OTHER EXEMPLARY EMBODIMENTS

The exemplary embodiment shows first member 10 and second member 20 each of which includes the semiconductor wafer as a main part. Besides this, any one of first member 10 and second member 20 may be a semiconductor chip obtained by dividing a semiconductor wafer. Alternatively, first member 10 and second member 20 each may be a semiconductor chip.

When first member 10 is a semiconductor chip in the second modification, second member 40 may be a wiring substrate equivalent in size to first member 10. As with second member 40, first member 10 may be a wiring substrate having a front surface provided with a metal pattern and an insulating film covering a side surface of the metal pattern. As in the first modification, a protrusion protruding from a corner of a front surface of second insulating film 46A may be provided on second member 40.

The configuration of hybrid bonding equipment 100 is not particularly limited to that illustrated in FIG. 3. For example, the configuration may include a loading chamber, plasma treatment chamber 130, hydrophilization treatment chamber 140, bonding treatment chamber 150, and an unloading chamber, which are connected in series in this order through conveyance path 170. This configuration eliminates conveyance chamber 160.

That is, hybrid bonding equipment 100 of the present disclosure includes at least plasma treatment chamber 130, hydrophilization treatment chamber 140, bonding treatment chamber 150, and conveyance path 170.

First member 10 and second members 20, 40 are configured to be movable to plasma treatment chamber 130, hydrophilization treatment chamber 140, and bonding treatment chamber 150 through conveyance path 170.

Plasma treatment chamber 130, hydrophilization treatment chamber 140, bonding treatment chamber 150, and conveyance path 170 are each controlled to have an internal atmosphere with cleanliness of a predetermined value or less.

Alternatively, a standby chamber may be separately provided in which a member having been subjected to the hydrophilization treatment first waits until the bonding treatment starts. The configuration illustrated in FIG. 3 may include an area corresponding to the standby chamber in conveyance chamber 160.

The present exemplary embodiment enables two members, each with a front surface provided with an electrode pattern and an insulating film, to be bonded to each other at low cost and favorably. Then, a component obtained by bonding the two members to each other can be improved in a manufacturing yield and reliability.

The method for manufacturing a component of the present disclosure enables two members, each with a front surface provided with an electrode pattern and an insulating film, to be bonded to each other at low cost and favorably, thus being useful.

What is claimed is:

1. A method for manufacturing a component that is obtained by bonding a first member and a second member, the method comprising:
a metal layer formation step of forming a first metal layer on a front surface of a first substrate;
a resist pattern formation step of forming a resist pattern on a front surface of the first metal layer;
a metal pattern formation step of forming a first metal pattern by removing the first metal layer using the resist pattern as a mask;
an insulating film formation step of forming a first insulating film on the front surface of the first substrate with the resist pattern left on a front surface of the first metal pattern;
a resist lift-off step of removing the first insulating film covering the resist pattern together with the resist pattern to obtain the first member with a front surface provided with the first metal pattern and the first insulating film provided covering a side surface of the first metal pattern;
a second member preparation step of preparing the second member in which a second metal pattern and a second insulating film provided covering a side surface of the second metal pattern are formed on a front surface of a second substrate;
a surface treatment step of performing predetermined treatment on the front surface of the first member after the resist lift-off step is performed, and on a front surface of the second member;
a bonding step of, after the surface treatment step is performed, aligning the first member and the second member such that the front surface of the first member and the front surface of the second member face each other, and bonding the first insulating film and the second insulating film; and
an annealing step of bonding the first metal pattern and the second metal pattern by heating the first member and the second member to a predetermined temperature after the surface treatment step is performed.

2. The method for manufacturing the component according to claim 1, wherein the metal pattern formation step is performed to remove the first metal layer using any one of wet etching, laser ablation, and plasma etching.

3. The method for manufacturing the component according to claim 1, wherein the resist lift-off step is performed to remove the first insulating film together with the resist pattern using a chemical solution of any one of an organic solvent, a developer, and an acidic solution.

4. The method for manufacturing the component according to claim 1, wherein the surface treatment step includes an activation step of performing plasma treatment on the front surface of each of the first member and the second member, and hydrophilization treatment of attaching moisture to the front surface of each of the first member and the second member following the activation step.

5. The method for manufacturing the component according to claim 4, wherein the plasma treatment uses any one or more kinds of inert gas, oxygen, hydrogen, chlorine, and fluorine, as gas.

6. The method for manufacturing the component according to claim 1, wherein the bonding step is performed at a temperature less than or equal to 200°C.

7. The method for manufacturing the component according to claim 1, wherein
the first insulating film is made of an inorganic material or an organic material, and
when the first insulating film is made of the inorganic material, the inorganic material is any one selected from among silicon oxide, silicon nitride, silicon carbonitride, zirconia oxide, and hafnium oxide.

8. The method for manufacturing the component according to claim 7, wherein the second insulating film is identical in material to the first insulating film.

9. The method for manufacturing the component according to claim 1, wherein
the first metal pattern includes a first layer exposed on the front surface of the first metal pattern, and
the first layer is made of copper or an alloy mainly composed of copper.

10. The method for manufacturing the component according to claim 9, wherein the first metal pattern further includes a second layer disposed between the first layer and the first substrate.

11. The method for manufacturing the component according to claim 10, wherein
the second metal pattern includes at least a third layer exposed on a front surface of the second metal pattern, and
the third layer is identical in material to the first layer.

12. The method for manufacturing the component according to claim 4, wherein the first metal pattern after the activation step is performed has a thinner thickness than the first insulating film.

13. The method for manufacturing the component according to claim 1, wherein the first metal pattern after the metal pattern formation step is performed has a shape in which a corner of a front surface of the first metal pattern is chamfered.

14. The method for manufacturing the component according to claim 1, wherein the first insulating film before the bonding step is performed has a protrusion protruding from a corner of a front surface thereof.

15. A component comprising:
a first member; and
a second member, wherein
the first member and the second member are bonded,
the first member includes a first metal pattern disposed on a front surface of a first substrate and a first insulating film covering a side surface of the first metal pattern,
the second member includes a second metal pattern disposed on a front surface of a second substrate and a second insulating film covering a side surface of the second metal pattern,
the first insulating film and the second insulating film are bonded, and the first metal pattern and the second metal pattern are bonded,
at least the first metal pattern includes a first layer exposed on a front surface of the first metal pattern, and a second layer disposed between the first layer and the first substrate, and
the second layer is not disposed between the side surface of the first metal pattern and a side surface of the first insulating film.

16. A hybrid bonding equipment configured to bond a first member and a second member, the first member including a first metal pattern disposed on a front surface of a first substrate and a first insulating film covering a side surface of the first metal pattern, and the second member including a second metal pattern disposed on a front surface of a second substrate and a second insulating film covering a side surface of the second metal pattern, the hybrid bonding equipment comprising:
a plasma treatment chamber;
a hydrophilization treatment chamber;
a bonding treatment chamber; and
a conveyance path, wherein
the first member and the second member are configured to be movable to the plasma treatment chamber, the hydrophilization treatment chamber, and the bonding treatment chamber through the conveyance path,
the plasma treatment chamber, the hydrophilization treatment chamber, the bonding treatment chamber, and the conveyance path are each controlled to have an internal atmosphere with cleanliness of a predetermined value or less,
the plasma treatment chamber is configured to perform plasma treatment on a front surface of each of the first member and the second member,
the hydrophilization treatment chamber is configured to perform hydrophilization treatment of attaching moisture to the front surface of each of the first member and the second member after the plasma treatment is performed, and
the bonding treatment chamber is configured to perform bonding treatment of bonding the first insulating film and the second insulating film performed the hydrophilization treatment, and annealing treatment of heating the first member and the second member to bond the first metal pattern to the second metal pattern.
